(19) United States
(12) Patent Application Publication
(10) Pub. No.: US 2026/0247940 A1
(43) Pub. Date: Aug. 20, 2026

(54) SEMICONDUCTOR PACKAGE INCLUDING VERTICALLY STACKED SEMICONDUCTOR CHIPS

(71) Applicant: Samsung Electronics Co., Ltd., Suwon-si (KR)

(72) Inventors: Sung Min Moon, Suwon-si (KR); Seok Woo Yoon, Suwon-si (KR)

(73) Assignee: Samsung Electronics Co., Ltd., Suwon-si (KR)

(21) Appl. No.: 19/368,039

(22) Filed: Oct. 24, 2025

(30) Foreign Application Priority Data
Feb. 19, 2025 (KR) 10-2025-0021401

(51) Int. Cl. H01L 23/00; H01L 23/31; H01L 23/48; H01L 25/065

(52) U.S. Cl. CPC H10W 20/20; H10W 74/131; H10W 90/00; H10W 72/325; H10W 72/353; H10W 72/354; H10W 74/15; H10W 90/722; H10W 90/732

(57) ABSTRACT

Provided is a semiconductor package. The semiconductor package according to some embodiments of the present disclosure includes a first semiconductor chip, a second semiconductor chip arranged on the first semiconductor chip, and a non-conductive structure arranged between the first semiconductor chip and the second semiconductor chip, wherein the non-conductive structure includes a filler including a plurality of pores.

### CROSS-REFERENCE TO RELATED APPLICATIONS

This present application claims priority to and the benefit under 35 U.S.C. § 119(a)-(d) of Korean Patent Application No. 10-2025-0021401, filed on Feb. 19, 2025, in the Korean Intellectual Property Office, the entire disclosure of which is incorporated herein by reference.

### BACKGROUND

The present disclosure relates to a semiconductor package.

With the lightweight and high performance of electronic devices, development of a semiconductor package with miniaturization and high performance have been required even in the field of the semiconductor package. Research and development of semiconductor packages with a structure in which semiconductor chips are vertically stacked have been continuously made to implement miniaturization, light weight, high performance and high reliability of the semiconductor packages.

### SUMMARY

An object of the present disclosure is to provide a semiconductor package with improved reliability.

The objects of the present disclosure are not limited to those mentioned above and additional objects of the present disclosure, which are not mentioned herein, will be clearly understood by those skilled in the art from the following description of the present disclosure.

A semiconductor package according to some embodiments of the present disclosure includes a first semiconductor chip, a second semiconductor chip arranged on the first semiconductor chip, and a non-conductive structure arranged between the first semiconductor chip and the second semiconductor chip, wherein the non-conductive structure includes a filler including a plurality of pores.

A semiconductor package according to some embodiments of the present disclosure includes a base chip, a semiconductor chip structure, in which a plurality of semiconductor chips are stacked, on the base chip, and a non-conductive structure, which includes a first non-conductive material layer and a second non-conductive material layer on the first non-conductive material layer, between the base chip and the semiconductor chip structure, wherein the first non-conductive material layer includes a first insulating layer and a first filler in the first insulating layer, the second non-conductive material layer includes a second insulating layer and a second filler in the second insulating layer, the first filler includes a plurality of pores, and the second filler does not include pores.

According to some embodiments, a method of manufacturing a semiconductor package includes providing a base chip, providing a semiconductor chip structure on the base chip, stacking a plurality of semiconductor chips in the semiconductor chip structure, providing a non-conductive structure, including a first non-conductive material layer and a second non-conductive material layer on the first non-conductive material layer, between the base chip and the semiconductor chip structure, wherein the first non-conductive material layer includes a first insulating layer and a first filler in the first insulating layer, the second non-conductive material layer includes a second insulating layer and a second filler in the second insulating layer, the first filler includes a plurality of pores, and the second filler does not include pores.

A semiconductor package according to some embodiments of the present disclosure includes a base chip, a semiconductor chip structure, in which a plurality of first and second semiconductor chips are sequentially stacked, on the base chip, and a first insulating structure, which includes a first non-conductive material layer and a second non-conductive material layer on the first non-conductive material layer, between the base chip and the first semiconductor chip, a second insulating structure, which includes a third non-conductive material layer and a fourth non-conductive material layer on the third non-conductive material layer, between the first semiconductor chip and the second semiconductor chip, a mold layer, which covers sides of each of the first and second semiconductor chips, on the base chip, and through vias passing through each of the first and second semiconductor chips, wherein the first non-conductive material layer includes a porous first filler, the second non-conductive material layer includes a second filler different from the first filler, the third non-conductive material layer includes a porous third filler, and the fourth non-conductive material layer includes a fourth filler different from the third filler.

### BRIEF DESCRIPTION OF THE DRAWINGS

FIG. 1 is a schematic plan view illustrating a semiconductor package according to some embodiments;

FIG. 2 is a cross-sectional view taken along line I-I′ of FIG. 1;

FIG. 3 is an enlarged view of a region R1 of FIG. 2;

FIG. 4 is an enlarged view of a region S1 of FIG. 3;

FIG. 5 is an enlarged view of a region R2 of FIG. 2;

FIG. 6 is an enlarged view of a region S2 of FIG. 5;

FIGS. 7 to 9 are views illustrating a non-conductive structure of a semiconductor package according to some embodiments;

FIG. 10 is a cross-sectional view illustrating a semiconductor package according to some embodiments;

FIGS. 11 to 13 are views illustrating intermediate steps to describe a method for fabricating a semiconductor package according to some embodiments;

FIG. 14 is a schematic plan view illustrating a semiconductor package according to some embodiments;

FIG. 15 is a cross-sectional view taken along line II-II′ of FIG. 14;

FIG. 16 is a cross-sectional view illustrating a semiconductor package according to some embodiments.

### DETAILED DESCRIPTION

Hereinafter, the embodiments according to the technical spirits of the present disclosure will be described in detail with reference to the accompanying drawings.

A thermal compression bonding process may be performed to vertically stack a plurality of semiconductor chips. During such a bonding process of a high temperature, a non-conductive film between the semiconductor chips may be thermally decomposed, thereby generating a by-product. Such a by-product may be a cause of deteriorating reliability of a semiconductor package.

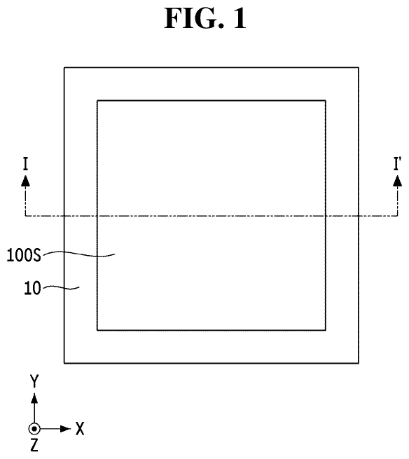

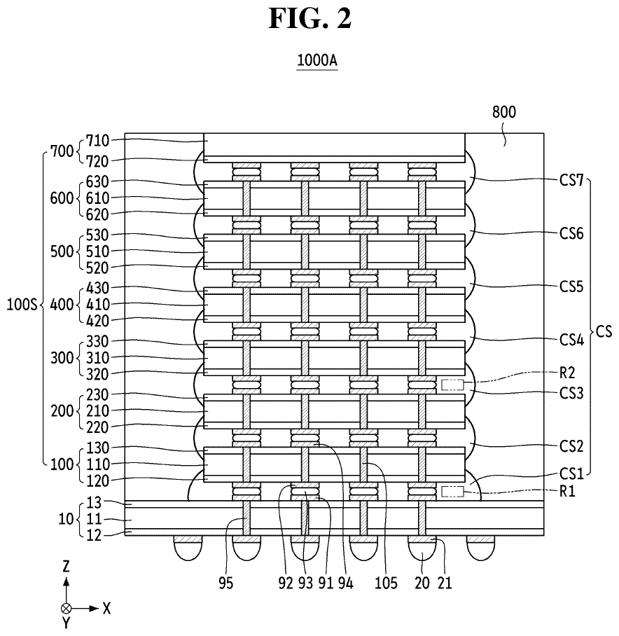

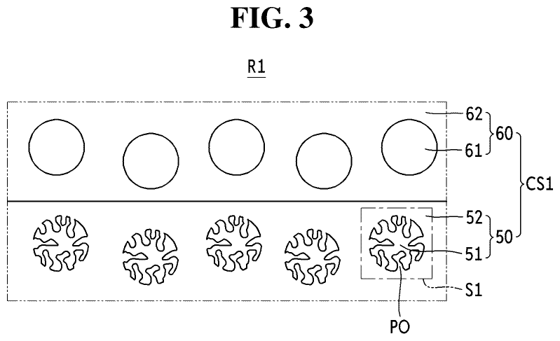

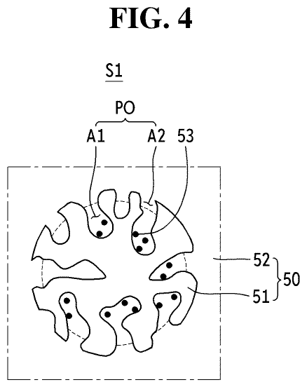

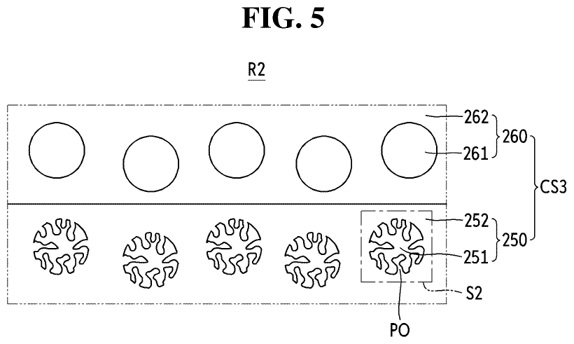

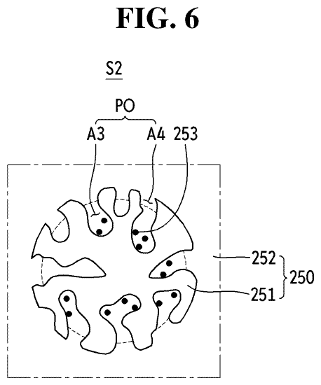

FIG. 1 is a schematic plan view illustrating a semiconductor package according to some embodiments. FIG. 2 is a cross-sectional view taken along line I-I′ of FIG. 1. FIG. 3 is an enlarged view of a region R1 of FIG. 2. FIG. 4 is an enlarged view of a region S1 of FIG. 3. FIG. 5 is an enlarged view of a region R2 of FIG. 2. FIG. 6 is an enlarged view of a region S2 of FIG. 5.

Referring to FIGS. 1 and 2, a semiconductor package 1000A according to some embodiments may include a base chip 10, an external connection terminal 20, a semiconductor chip stack structure 100S, a non-conductive material structure CS, a mold layer 800, and through vias 105.

The base chip 10 may include an upper surface and a lower surface, which face one another. The upper surface of the base chip 10 may be a surface on which the semiconductor chip stack structure 100S is formed, and the lower surface of the base chip 10 may be a surface on which lower pads 21 to be described later are formed. The upper surface of the base chip 10 may extend respectively in first and second horizontal directions X and Y crossing one another perpendicularly. The semiconductor chip stack structure 100S may be stacked on the upper surface of the base chip 10 in a third direction Z perpendicular to each of the first and second horizontal directions X and Y.

The base chip 10 may include a substrate 11, an upper protective layer 13, an upper pad 91, a lower pad 21, an element layer 12, and through vias 95. The base chip 10 may be, for example, a buffer chip including a plurality of logic elements and/or memory elements in the element layer 12. Accordingly, the base chip 10 may transfer signals from a plurality of semiconductor chips 100 to 700 stacked thereon to the outside, and may also transfer signals and power from the outside to the plurality of semiconductor chips 100 to 700. The base chip 10 may perform a logic function and a memory function together through the logic elements and the memory elements, but the base chip 10 may include only logic elements to perform a logic function depending on the embodiments.

The substrate 11 may include, for example, a semiconductor element such as silicon (Si) or germanium (Ge), or a compound semiconductor such as silicon carbide (SiC), gallium arsenide (GaAs), indium arsenide (InAs), or indium phosphide (InP). The substrate 11 may have a silicon-on-insulator (SOI) structure. The substrate 11 may include a conductive region, for example, an impurity-doped well or an impurity-doped structure. The substrate 11 may include various element isolation structures such as a shallow trench isolation (STI) structure.

The upper protective layer 13 may be formed on an upper surface of the substrate 11, and may protect the substrate 11. The upper protective layer 13 may include an insulating layer such as a silicon oxide layer, a silicon nitride layer, or a silicon oxynitride layer, but the material of the upper protective layer 13 is not limited to thereto. For example, the upper protective layer 13 may include a polymer such as polyimide (PI) or photoresistive polyimide (PSPI). Although not shown in detail, a lower protective layer may be further formed on a lower surface of the element layer 12.

The upper pad 91 may be arranged on an upper surface of the base chip 10 or on an upper portion of the upper protective layer 13. The upper pad 91 may include at least one of, for example, aluminum (Al), copper (Cu), nickel (Ni), tungsten (W), platinum (Pt) or gold (Au). The lower pad 21 may be arranged on a lower surface of the base chip 10 or below the element layer 12, and may include a material similar to that of the upper pad 91. However, the materials of the upper pad 91 and the lower pad 21 are not limited to the above materials.

The element layer 12 is arranged on a lower surface of the substrate 11, and may include various types of elements. For example, the element layer 12 may include a Field Effect Transistor (FET) such as a planar FET or a FinFET, a memory element such as a flash memory, a Dynamic Random Access Memory (DRAM), a Static Random Access Memory (SRAM), an Electrically Erasable Programmable Read-Only Memory (EEPROM), a Phase-change Random Access Memory (PRAM), a Magnetoresistive Random Access Memory (MRAM), a Ferroelectric Random Access Memory (FeRAM), and a Resistive Random Access Memory (RRAM), a logic element such as AND, OR, and NOT, and various active elements and/or passive elements such as system Large Scale Integration (LSI), a CMOS Imaging Sensor (CIS), and a Micro-Electro-Mechanical System (MEMS).

The element layer 12 may include an interlayer insulating layer (not shown) and a multi-layered wiring layer (not shown) on the above-described elements. The interlayer insulating layer (not shown) may include silicon oxide or silicon nitride. The multi-layered wiring layer (not shown) may include multi-layered wirings and/or a vertical contact. The multi-layered wiring layer (not shown) may connect the elements of the element layer 12 to one another, connect the elements to a conductive region of the substrate 11, or connect the elements to the lower pad 21.

The through vias 95 pass through the substrate 11 in the third direction Z, and may provide an electrical path for connecting the upper pad 91 to the lower pads 21. The through vias 95 may be electrically connected to the plurality of semiconductor chips 100 to 700. Although not shown in detail, the through vias 95 may include a conductive plug and a barrier film surrounding the conductive plug. The conductive plug may include a metal material, for example, tungsten (W), titanium (Ti), aluminum (Al), or copper (Cu). The conductive plug may be formed by a plating process, a PVD process, or a CVD process. The barrier film includes titanium (Ti), titanium nitride (TiN), tantalum (Ta), or tantalum nitride (TaN), and may be formed by a plating process, a PVD process, or a CVD process. A side insulating layer (not shown) containing an insulating material (e.g., high aspect ratio process (HARP) oxide) such as silicon oxide, silicon nitride, or silicon oxynitride may be formed between sides of the through vias 95 and the substrate 11.

Connection bumps 20 may be arranged below the base chip 10. The connection bumps 20 may be electrically connected to the plurality of semiconductor chips 100 to 700 through the through vias 95. The connection bumps 20 may include, for example, tin (Sn) or an alloy (e.g., Sn—Ag—Cu) containing tin (Sn). According to an embodiment, the connection bumps 20 may have a form in which a metal pillar and a solder ball are combined with one another. The connection bumps 20 may be electrically connected to an external device such as a module substrate and a system board. The base chip 10 may have a width greater than that of each of the plurality of semiconductor chips 100 to 700 in the first horizontal direction X and/or the second horizontal direction Y. At least a portion of the connection bumps 20 and at least a portion of the lower pads 21 may be arranged at positions that do not overlap the plurality of semiconductor chips 100 to 700 in the third direction Z.

The semiconductor chip stack structure 100S may include a plurality of semiconductor chips 100 to 700 sequentially stacked in the third direction Z. The plurality of semiconductor chips 100 to 700 may include memory chips or memory elements, which store or output data based on an address command and a control command, which are received from the base chip 10. For example, the plurality of semiconductor chips 100 to 700 may include volatile memory elements such as DRAM and SRAM, or nonvolatile memory elements such as PRAM, MRAM, FeRAM or RRAM.

The plurality of semiconductor chips 100 to 700 may include a first semiconductor chip 100, a second semiconductor chip 200, a third semiconductor chip 300, a fourth semiconductor chip 400, a fifth semiconductor chip 500, a sixth semiconductor chip 600, and a seventh semiconductor chip 700, which are sequentially stacked on the base chip 10.

The first semiconductor chip 100 may be arranged on the base chip 10. The first semiconductor chip 100 may include a first substrate 110, a first rear protective layer 130, first front pads 92 arranged on a first front surface, first rear pads 94 arranged on a first rear surface, a first element layer 120, and first through vias 105 electrically connecting the first front pads 92 to the first rear pads 94. The first substrate 110, the first rear protective layer 130, the first front pads 92, the first rear pads 94, the first element layer 120, and the first through vias 105 have the same or similar characteristics as or to those of the base chip 10, that is, the substrate 11, the upper protective layer 13, the lower pad 21, the upper pad 91, the element layer 12, and the through vias 95, and thus their repeated description will be omitted.

The first semiconductor chip 100 may have a first front surface on which the first front pads 92 are arranged, a first rear surface on which the first rear pads 94 are arranged, and a first side extending from an edge of the first front surface to an edge of the first rear surface.

The second semiconductor chip 200 is arranged on the first semiconductor chip 100, and may include a second substrate 210, a second rear protective layer 230, second front pads arranged on the second front surface, second rear pads arranged on the second rear surface, a second element layer 220, and second through vias electrically connecting the second front pads to the second rear pads. The second substrate 210, the second rear protective layer 230, the second front pads, the second rear pads, the second element layer 220, and the second through vias have the same or similar characteristics as or to those of the base chip 10, that is, the substrate 11, the upper protective layer 13, the lower pad 21, the upper pad 91, the element layer 12, and the through vias 95, and thus their repeated description will be omitted.

The second semiconductor chip 200 may have a second front surface on which the second front pads are arranged, a second rear surface on which the second rear pads are arranged, and a second side extending from an edge of the second front surface to an edge of the second rear surface. According to the embodiment, the number of second semiconductor chips 200 may be one or two or more. The plurality of second semiconductor chips 200 may be electrically connected to one another through the second through vias electrically connecting the second front pads to the second rear pads.

The third semiconductor chip 300 is arranged on the second semiconductor chip 200, and may include a third substrate 310, a third rear protective layer 330, third front pads arranged on a third front surface, third rear pads arranged on a third rear surface, a third element layer 320, and third through vias electrically connecting the third front pads to the third rear pads. The third substrate 310, the third rear protective layer 330, the third rear pads, the third rear pads 320, and the third through vias have the same or similar characteristics as or to those of the base chip 10, that is, the substrate 11, the upper protective layer 13, the lower pad 21, the upper pad 91, the element layer 12, and the through vias 95, and thus their repeated description will be omitted.

The third semiconductor chip 300 may have a third front surface on which the third front pads are arranged, a third rear surface on which the third rear pads are arranged, and a third side extending from an edge of the third front surface to an edge of the third rear surface. According to the embodiment, the number of third semiconductor chips 300 may be one or two or more. The plurality of third semiconductor chips 300 may be electrically connected to one another through the third through vias electrically connecting the third front pads to the third rear pads.

The fourth semiconductor chip 400 is arranged on the third semiconductor chip 300, and may include a fourth substrate 410, a fourth rear protective layer 430, fourth front pads arranged on a fourth front surface, fourth rear pads arranged on a fourth rear surface, a fourth element layer 420, and fourth through vias electrically connecting the fourth front pads to the fourth rear pads. The fourth substrate 410, the fourth rear protective layer 430, the fourth front pads, the fourth rear pads, the fourth element layer 420, and the fourth through vias have the same or similar characteristics as or to those of the base chip 10, that is, the substrate 11, the upper protective layer 13, the lower pad 21, the upper pad 91, the element layer 12, and the through vias 95, and thus their repeated description will be omitted.

The fourth semiconductor chip 400 may have a fourth front surface on which the fourth front pads are arranged, a fourth rear surface on which the fourth rear pads are arranged, and a fourth side extending from an edge of the fourth front surface to an edge of the fourth rear surface. According to the embodiment, the number of the fourth semiconductor chips 400 may be one or two or more. The plurality of fourth semiconductor chips 400 may be electrically connected to one another through the fourth through vias electrically connecting the fourth front pads to the fourth rear pads.

The fifth semiconductor chip 500 is arranged on the fourth semiconductor chip 400, and may include a fifth substrate 510, a fifth rear protective layer 530, fifth front pads arranged on a fifth front surface, fifth rear pads arranged on a fifth rear surface, a fifth element layer 520, and fifth through vias electrically connecting the fifth front pads to the fifth rear pads. The fifth substrate 510, the fifth rear protective layer 530, the fifth rear pads, the fifth element layer 520, and the fifth through vias have the same or similar characteristics as or to those of the base chip 10, the substrate 11, the upper protective layer 13, the lower pad 21, the upper pad 91, the element layer 12, and the through vias 95, and thus their repeated description will be omitted.

The fifth semiconductor chip 500 may have a fifth front surface on which the fifth front pads are arranged, a fifth rear surface on which the fifth rear pads are arranged, and a fifth side extending from an edge of the fifth front surface to an edge of the fifth rear surface. According to the embodiment, the number of fifth semiconductor chips 500 may be one or two or more. The plurality of fifth semiconductor chips 500 may be electrically connected to one another through the fifth through vias electrically connecting the fifth front pads to the fifth rear pads.

The sixth semiconductor chip 600 is arranged on the fifth semiconductor chip 500, and may include a sixth substrate 610, a sixth rear protective layer 630, sixth front pads arranged on a sixth front surface, sixth rear pads arranged on a sixth rear surface, a sixth element layer 620, and sixth through vias electrically connecting the sixth front pads to the sixth rear pads. The sixth substrate 610, the sixth rear protective layer 630, the sixth front pads, the sixth rear pads, the sixth element layer 620, and the sixth through vias have the same or similar characteristics as or to those of the base chip 10, that is, the substrate 11, the upper protective layer 13, the lower pad 21, the upper pad 91, the element layer 12, and the through vias 95, and thus their repeated description will be omitted.

The sixth semiconductor chip 600 may have a sixth front surface on which the sixth front pads are arranged, a sixth rear surface on which the sixth rear pads are arranged, and a sixth side extending from an edge of the sixth front surface to an edge of the sixth rear surface. According to the embodiment, the number of the sixth semiconductor chips 600 may be one or two or more. The plurality of sixth semiconductor chips 600 may be electrically connected to one another through the sixth through vias electrically connecting the sixth front pads to the sixth rear pads.

The seventh semiconductor chip 700 is arranged on the sixth semiconductor chip 600, and may include a seventh substrate 710, seventh front pads, and a seventh element layer 720. The seventh substrate 710, the seventh front pads, and the seventh element layer 720 have the same or similar characteristics as or to those of the base chip 10, that is, the substrate 11, the upper protective layer 13, the lower pad 21, the upper pad 91, the element layer 12, and the through vias 95, and thus their repeated description will be omitted.

The seventh semiconductor chip 700 may have a seventh front surface on which the seventh front pads are arranged, a seventh rear surface opposite to the seventh front surface, and a seventh side extending from an edge of the seventh front surface to an edge of the seventh rear surface. The seventh semiconductor chip 700 may be arranged on an uppermost side of the plurality of semiconductor chips 100 to 700, and the seventh rear surface may be exposed from the mold layer 800, but the present disclosure is not limited thereto. The seventh semiconductor chip 700 may have a thickness different from that of each of the plurality of semiconductor chips 100 to 600, but the present disclosure is not limited thereto.

Only seven semiconductor chips included in the semiconductor chip stack structure 100S are shown in FIG. 2, but the present disclosure is not limited thereto, and the number of semiconductor chips included in the semiconductor chip stack structure 100S may vary.

Bump structures 93 may be arranged between the plurality of semiconductor chips 100 to 700. The bump structures 93 may electrically connect pads facing one another. For example, the bump structures 93 may be arranged between the upper surface of the base chip 10 and the first front surface of the first semiconductor chip 100, between the first semiconductor chip 100 and the second front surface of the second semiconductor chip 200, between the second semiconductor chip 200 and the third front surface of the third semiconductor chip 300, between the third semiconductor chip 300 and the fourth front surface of the fourth semiconductor chip 400, between the fourth semiconductor chip 400 and the fifth front surface of the fifth semiconductor chip 500, between the fifth semiconductor chip 500 and the sixth front surface of the sixth semiconductor chip 600, between the sixth semiconductor chip 600 and the seventh front surface of the seventh semiconductor chip 700.

The bump structures 93 may include, for example, tin (Sn), indium (In), bismuth (Bi), antimony (Sb), copper (Cu), silver (Ag), zinc (Zn), lead (Pb), and/or their alloys. The alloys may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, etc.

The non-conductive material structure CS may include a first non-conductive structure CS1 and second to seventh non-conductive structures CS2 to CS7 on the first non-conductive structure CS1. The first to seventh non-conductive structures CS1 to CS7 may be sequentially arranged on the base chip 10.

The first non-conductive structure CS1 may be arranged between the base chip 10 and the first semiconductor chip 100. The first non-conductive structure CS1 may surround some bump structures, which are arranged between the base chip 10 and the first semiconductor chip 100, among the bump structures 93, and may fix the plurality of semiconductor chips 100 to 700 onto the base chip 10.

The second to seventh non-conductive structures CS2 to CS7 may be arranged between the plurality of semiconductor chips 100 to 700. The second non-conductive structure CS2 may be arranged between the first semiconductor chip 100 and the second semiconductor chip 200. The third non-conductive structure CS3 may be arranged between the second semiconductor chip 200 and the third semiconductor chip 300. The fourth non-conductive structure CS4 may be arranged between the third semiconductor chip 300 and the fourth semiconductor chip 400. The fifth non-conductive structure CS5 may be arranged between the fourth semiconductor chip 400 and the fifth semiconductor chip 500. The sixth non-conductive structure CS6 may be arranged between the fifth semiconductor chip 500 and the sixth semiconductor chip 600. The seventh non-conductive structure CS7 may be arranged between the sixth semiconductor chip 600 and the seventh semiconductor chip 700.

The second to seventh non-conductive structures CS2 to CS7 may surround some bump structures, which are arranged between the plurality of semiconductor chips 100 to 700, among the bump structures 93, and may fix the plurality of semiconductor chips 200 to 700 onto the base chip 10.

The first non-conductive structure CS1 and the second to seventh non-conductive structures CS2 to CS7 may be non-conductive films (NCF), but are not limited thereto, and may include, for example, any type of polymer film capable of enabling a thermal compression process.

Referring to FIG. 3, the first non-conductive structure CS1 may include a first non-conductive material layer 50 and a second non-conductive material layer 60 on the first non-conductive material layer 50.

The first non-conductive material layer 50 may include first fillers 51 and a first insulating layer 52. The first fillers 51 may be filler particles dispersed in the first insulating layer 52. For example, the first insulating layer 52 may include a polymer such as an epoxy resin, and the first fillers 51 may include inorganic fillers having a diameter of 1 μm or less, but the present disclosure is not limited thereto. For example, the first fillers 51 may include ceramic particles having a diameter of 1 nm to 50 nm. For example, the first fillers 51 may include at least one of SiO₂, ZrO₃, HfO₂ and/or TiO₂, but are not limited thereto.

The first fillers 51 may be porous fillers. Each of the first fillers 51 may include a plurality of pores PO. For example, the porosity of the first non-conductive material layer 50 may be 10% or more and 100% or less. That is, in the first non-conductive material layer 50, a ratio of the first fillers 51 may be 10% or more and 100% or less.

The second non-conductive material layer 60 may include second fillers 61 and a second insulating layer 62. The second fillers 61 may be filler particles dispersed in the second insulating layer 62. The second insulating layer 62 may include, for example, a polymer such as an epoxy resin, and the second fillers 61 may include inorganic fillers having a diameter of 1 μm or less, but the present disclosure is not limited thereto. For example, the second non-conductive material layer 60 may be provided in a form in which about 80% or more of the second fillers 61 having a diameter of 1 μm or less are filled. For example, the second fillers 61 may include ceramic particles having a diameter of 100 nm to 10 μm. For example, the second fillers 61 may include at least one of SiO₂, ZrO₃, HfO₂ and/or TiO₂, but are not limited thereto.

In some embodiments, the second fillers 61 may not include pores, unlike the first fillers 51. However, as will be described later, the second fillers 61 may include a plurality of pores depending on the embodiment.

A size of each of the first fillers 51 may be the same as a size of each of the second fillers 61. However, the size of each of the first fillers 51 may be different from the size of each of the second fillers 61 depending on the embodiment. In this case, the size of each of the first fillers 51 may be smaller than the size of each of the second fillers 61, but the present disclosure is not limited thereto.

The first insulating layer 52 and the second insulating layer 62 may include different materials from one another. The first insulating layer 52 and the second insulating layer 62 may have different viscosities from one another. For example, the viscosity of the first insulating layer 52 may be lower than that of the second insulating layer 62. In this case, the lowest viscosity (or the highest viscosity) of the first insulating layer 52 at a predetermined temperature may be lower than the lowest viscosity (or the highest viscosity) of the second insulating layer 62 at the predetermined temperature.

In FIG. 2, the non-conductive material structure CS is shown to partially extend on the side of the semiconductor chip stack structure 100S, but the non-conductive material structure CS may further extend on the side of the semiconductor chip stack structure 100S. Furthermore, the non-conductive material structure CS may completely cover the side of the semiconductor chip stack structure 100S.

Referring to FIG. 4, in any one of the first fillers 51, at least one of the plurality of pores PO may include a first region A1 and a second region A2 on the first region A1. For example, the first region A1 may be an innermost region of the pore PO, and the second region A2 may be a region arranged farther outside the pore PO than the first region A1.

The first region A1 may be a region to which a pyrolysis product 53 of the first non-conductive structure CS1 is adsorbed in a thermal compression bonding process to be described later. The insulating material included in the first insulating layer 52 may not be filled in the first region A1. For example, the pyrolysis product 53 in the first region A1 may include a gaseous material. For example, the pyrolysis product 53 in the first region A1 may include air or a carbon (C) compound, but is not limited thereto. For example, the pyrolysis product 53 of the first region A1 may be a compound containing at least one of carbon (C), oxygen (O), nitrogen (N), or hydrogen (H). The second region A2 may include a polymer. The second region A2 may include the same insulating material as the material included in the first insulating layer 52.

The surface and/or cross-sectional analysis of the pores PO according to some embodiments may be performed using a transmission electron microscope (TEM) or a scanning electron microscope (SEM). Accordingly, a pore structure in the filler may be confirmed. In addition, the pyrolysis product 53 according to some embodiments may be analyzed for components using gas chromatography or the like. The material in the pore PO may be extracted to confirm that the pyrolysis product containing a carbon compound or the like is present in the filler.

Referring to FIG. 5, the third non-conductive structure CS3 may include a third non-conductive material layer 250 and a fourth non-conductive material layer 260 on the third non-conductive material layer 250.

The third non-conductive material layer 250 may include third fillers 251 and a third insulation layer 252. The third fillers 251 may be filler particles dispersed in the third insulation layer 252. The third insulation layer 252 may include, for example, a polymer such as an epoxy resin, and the second fillers 251 may include inorganic fillers having a diameter of 1 μm or less, but the present disclosure is not limited thereto. For example, the third fillers 251 may include ceramic particles having a diameter of 1 nm to 50 nm. For example, the third fillers 251 may include at least one of SiO₂, ZrO₃, HfO₂ and/or TiO₂, but are not limited thereto.

The third fillers 251 may be porous fillers. Each of the third fillers 251 may include a plurality of pores PO. For example, the porosity of the third non-conductive material layer 250 may be 10% or more and 100% or less. That is, in the third non-conductive material layer 250, a ratio of the third fillers 251 may be 10% or more and 100% or less.

The fourth non-conductive material layer 260 may include fourth fillers 261 and a fourth insulation layer 262. The fourth fillers 261 may be filler particles dispersed in the fourth insulation layer 262. The fourth insulation layer 262 may include, for example, a polymer such as an epoxy resin, and the fourth fillers 261 may include inorganic fillers having a diameter of 1 μm or less, but are not limited thereto. For example, the fourth fillers 261 may include ceramic particles having a diameter of 100 nm to 10 μm. For example, the fourth fillers 261 may include at least one of SiO₂, ZrO₃, HfO₂ and/or TiO₂, but are not limited thereto.

In some embodiments, the fourth fillers 261 may not include pores, unlike the third fillers 251. However, the fourth fillers 261 may include a plurality of pores depending on the embodiments.

A size of each of the third fillers 251 may be the same as a size of each of the fourth fillers 261. However, a size of each of the third fillers 251 may be different from a size of each of the fourth fillers 261 depending on the embodiments. In this case, a size of each of the third fillers 251 may be smaller than a size of each of the fourth fillers 261, but the present disclosure is not limited thereto.

The third insulating layer 252 and the fourth insulating layer 262 may include different materials from one another. The third insulating layer 252 and the fourth insulating layer 262 may have different viscosities from one another. For example, the viscosity of the third insulating layer 252 may be lower than that of the fourth insulating layer 262. In this case, the lowest viscosity (or the highest viscosity) of the third insulating layer 252 at a predetermined temperature may be lower than the lowest viscosity (or the highest viscosity) of the fourth insulating layer 262 at the predetermined temperature.

Referring to FIG. 6, in any one of the third fillers 251, at least one of the plurality of pores PO may include a third region A3 and a fourth region A4 on the third region A3. For example, the third region A3 may be an innermost region of the pore PO, and the fourth region A4 may be a region arranged farther outside the pore PO than the third region A3.

The third region A3 may be a region to which a pyrolysis product 253 of the third non-conductive structure CS3 is adsorbed in a thermal compression bonding process to be described later. The insulating material included in the third insulating layer 252 may not be filled in the third region A3. For example, the pyrolysis product 253 in the third region A3 may include a gaseous material. For example, the pyrolysis product 253 in the third region A3 may include air or a carbon (C) compound, but is not limited thereto. For example, the pyrolysis product 253 of the third region A3 may be a compound containing at least one of carbon (C), oxygen (O), nitrogen (N), or hydrogen (H). The fourth region A4 may include a polymer. The fourth region A4 may include the same insulating material as the material included in the third insulating layer 252.

The surface and/or cross-sectional analysis of the pores PO according to some embodiments may be performed using a transmission electron microscope (TEM) or a scanning electron microscope (SEM). Accordingly, a pore structure in the filler may be confirmed. In addition, the pyrolysis product 523 according to some embodiments may be analyzed for components using gas chromatography or the like. The material in the pores PO may be extracted to confirm that the pyrolysis product containing a carbon compound or the like is present in the filler.

Although not shown in detail, the second non-conductive structure CS2 and the fourth to seventh non-conductive structures CS4 to CS7 of FIG. 2 may include fillers and insulating layers as in the first non-conductive structure CS1 described using FIGS. 3 and 4 and the third non-conductive structure CS3 described using FIGS. 5 and 6. In this case, each of the second non-conductive structure CS4 and the fourth to seventh non-conductive structures CS4 to CS7 may include at least one filler including a plurality of pores.

In other words, the description of each of the first non-conductive structure CS1 described using FIGS. 3 and 4 and the third non-conductive structure CS3 described using FIGS. 5 and 6 may be applied to the second non-conductive structure CS2 and the fourth to seventh non-conductive structures CS4 to CS7 of FIG. 2 in the same manner.

The mold layer 800 may seal the plurality of semiconductor chips 100 to 700 on the base chip 10. The mold layer 800 may be formed to expose the rear surface of the seventh semiconductor chip 700. According to the embodiments, the mold layer 800 may be formed to cover the rear surface of the seventh semiconductor chip 700. The mold layer 800 may be formed of an insulating material, such as epoxy mold compound (EMC), but the material of the mold layer 800 is not limited thereto.

The mold layer 800 may cover sides of the plurality of semiconductor chips 100 to 700. The mold layer 800 may surround the sides of the plurality of semiconductor chips 100 to 700. The mold layer 800 may be in direct contact with the sides of each of the plurality of semiconductor chips 100 to 700 and sides of each of the non-conductive structures CS1 to CS7. The mold layer 800 may be arranged between the base chip 10 and the first semiconductor chip 100. The mold layer 800 may surround the bump structures 93 arranged between the base chip 10 and the first semiconductor chip 100. The mold layer 800 may be in direct contact with the bump structures 93 arranged between the base chip 10 and the first semiconductor chip 100.

Although not shown in detail, a heat dissipation structure (not shown) may be arranged on an upper portion of the mold layer 800. The heat dissipation structure (not shown) may control warpage of the semiconductor package 1000A and dissipate heat generated from the plurality of semiconductor chips 100 to 700 to the outside.

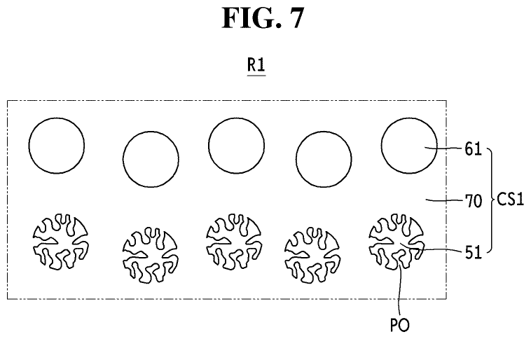

FIGS. 7 to 9 are views illustrating a non-conductive structure of a semiconductor package according to some embodiments. For convenience of description, redundant portions of those described above with reference to FIGS. 1 to 6 will be briefly described or omitted. For reference, FIGS. 7, 8, and 9 are views respectively corresponding to FIG. 3.

Referring to FIG. 7, unlike FIG. 3, the non-conductive structure CS1 may include one insulating layer instead of a plurality of insulating layers.

The non-conductive structure CS1 may include first fillers 51, second fillers 61, and an insulating layer 70 in which the first and second fillers 51 and 61 are mixed and dispersed. The first filler 51 may be a porous filler having pores PO, and the second filler 61 may be a filler having no pores.

For example, the insulating layer 70 may be formed as one insulating layer as a first insulating layer (52 of FIG. 3) and a second insulating layer (62 of FIG. 3) do not have a boundary surface by being thermally compressed in a thermal compression bonding process described later. Alternatively, the insulating layer 70 may be formed as one insulating layer instead of a plurality of insulating layers.

Although not shown in detail, the third non-conductive structure CS3 of FIG. 5 may include one insulating layer instead of a plurality of insulating layers. For example, the third non-conductive structure CS3 may include one insulating layer as a third insulating layer (252 of FIG. 5) and a fourth insulating layer (262 of FIG. 5) do not have a boundary surface by being thermally compressed. Alternatively, the third non-conductive structure CS3 may include one insulating layer instead of a plurality of insulating layers.

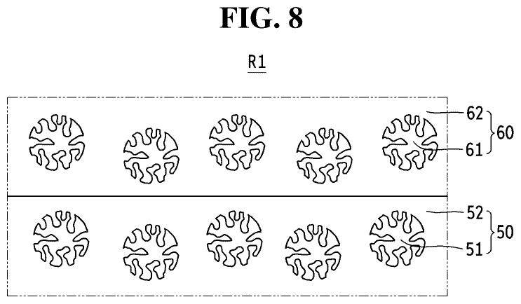

Referring to FIG. 8, the first non-conductive material layer 50 may include porous first fillers 51 and a first insulating layer 52. The second non-conductive material layer 60 may include porous second fillers 61 and a second insulating layer 62. Unlike FIG. 3, the second fillers 61 of FIG. 8 may be porous fillers. That is, the first fillers 51 and the second fillers 61 may be fillers of a single type.

The description of the first fillers 51 and the first insulating layer 52 described using FIGS. 1 to 7 may be applied to the first fillers 51 and the first insulating layer 52 of FIG. 8 in the same manner. The description of the second insulating layer 62 described using FIGS. 1 to 7 may be applied to the second insulating layer 62 of FIG. 8 in the same manner.

Although not shown in detail, each of the first and second insulating layers 52 and 62 of FIG. 8 may be formed as one insulating layer instead of a plurality of insulating layers.

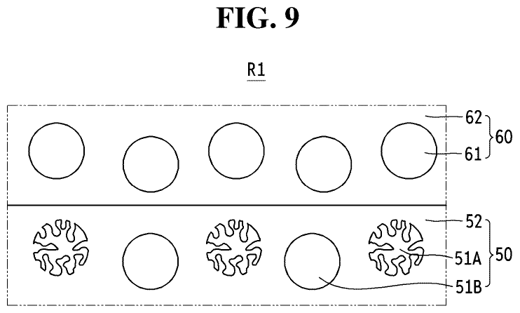

Referring to FIG. 9, the first non-conductive material layer 50 may further include porous first fillers 51A and fifth fillers 51B having no pores. The second non-conductive material layer 60 may include second fillers 61 having no pores and a second insulating layer 62. That is, the first non-conductive material layer 50 may include different types of fillers.

The description of the first fillers 51 described using FIGS. 1 to 8 may be applied to the first fillers 51A of FIG. 9 in the same manner. The description of the second fillers 61 described using FIGS. 1 to 8 may be applied to the fifth fillers 51B of FIG. 9 in the same manner.

For example, the porosity of the first non-conductive material layer 50 may be 10% or more and less than 100%. In the first non-conductive material layer 50, a ratio of the first fillers 51A having pores may be 10% or less and less than 100%.

Although not shown in detail, each of the first and second insulating layers 52 and 62 of FIG. 9 may be formed as one insulating layer instead of a plurality of insulating layers.

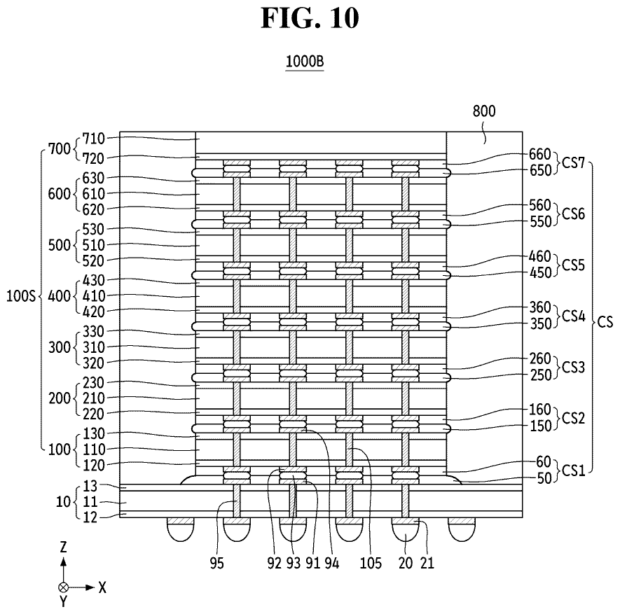

FIG. 10 is a cross-sectional view illustrating a semiconductor package according to some embodiments. For convenience of description, redundant portions of those described above with reference to FIGS. 1 to 9 will be briefly described or omitted. For reference, FIG. 10 is a view corresponding to FIG. 2.

Referring to FIG. 10, in a semiconductor package 1000B according to some embodiments, each of the first to seventh non-conductive structures CS1 to CS7 may include regions having different widths.

The first non-conductive structure CS1 may include a (1_1)th non-conductive material layer 50 and a (1_2)th non-conductive material layer 60, which have different widths from one another. For example, the width of the (1_1)th non-conductive material layer 50 may be greater than the width of the (1_2)th non-conductive material layer 60 based on the first horizontal direction X.

The second non-conductive structure CS2 may include a (2_1)th non-conductive material layer 150 and a (2_2)th non-conductive material layer 160, which have different widths from one another. For example, the width of the (2_1)th non-conductive material layer 150 may be greater than the width of the (2_2)th non-conductive material layer 160 based on the first horizontal direction X.

The third non-conductive structure CS3 may include a (3_1)th non-conductive material layer 250 and a (3_2)th non-conductive material layer 260, which have different widths from one another. For example, the width of the (3_1)th non-conductive material layer 250 may be greater than the width of the (3_2)th non-conductive material layer 260 based on the first horizontal direction X.

The fourth non-conductive structure CS4 may include a (4_1)th non-conductive material layer 350 and a (4_2)th non-conductive material layer 360, which have different widths from one another. For example, the width of the (4_1)th non-conductive material layer 350 may be greater than the width of the (4_2)th non-conductive material layer 360 based on the first horizontal direction X.

The fifth non-conductive structure CS5 may include a (5_1)th non-conductive material layer 450 and a (5_2)th non-conductive material layer 460, which have different widths from one another. For example, the width of the (5_1)th non-conductive material layer 450 may be greater than the width of the (5_2)th non-conductive material layer 460 based on the first horizontal direction X.

The sixth non-conductive structure CS6 may include a (6_1)th non-conductive material layer 550 and a (6_2)th non-conductive material layer 560, which have different widths from one another. For example, the width of the (6_1)th non-conductive material layer 550 may be greater than the width of the (6_2)th non-conductive material layer 560 based on the first horizontal direction X.

The seventh non-conductive structure CS7 may include a (7_1)th non-conductive material layer 650 and a (7_2)th non-conductive material layer 660, which have different widths. For example, the width of the (7_1)th non-conductive material layer 650 may be greater than the width of the (7_2)th non-conductive material layer 660 based on the first horizontal direction X.

Although not shown in detail, the non-conductive material structure CS may further extend on the side of the semiconductor chip stack structure 100S.

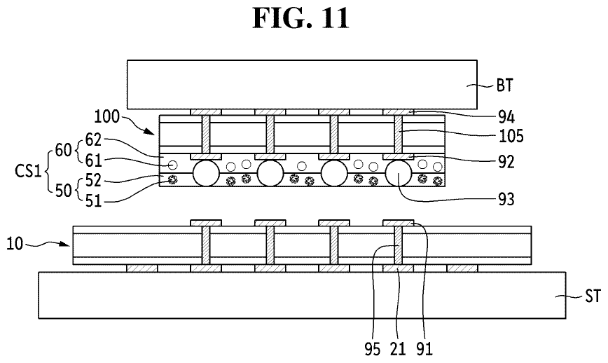

FIGS. 11 to 13 are views illustrating intermediate steps to describe a method for fabricating a semiconductor package according to some embodiments. For convenience of description, redundant portions of those described above with reference to FIGS. 1 to 10 will be briefly described or omitted. For reference, FIGS. 11 to 13 are views illustrating a method for fabricating the semiconductor package described with reference to FIGS. 1 to 6.

Referring to FIG. 11, a base chip 10 is provided on a stage ST. Lower pads 21 may be formed on a lower surface of the base chip 10, and upper pads 91 may be formed on an upper surface of the base chip 10. Through vias 95 passing through the base chip 10 may be formed between the lower pads 21 and the upper pads 91.

A first semiconductor chip 100 is provided on the upper surface of the base chip 10. A bonding tool BT is provided on the first semiconductor chip 100. First front pads 92 may be formed on a front surface of the first semiconductor chip 100, and first rear pads 94 may be formed on a rear surface of the first semiconductor chip 100. First through vias 105 passing through the inside of the first semiconductor chip 100 may be formed between the first front pads 92 and the first rear pads 94. Bump structures 93 may be formed below the first front pads 92.

A first non-conductive structure CS1 may be formed on the front surface of the first semiconductor chip 100 to surround sides of the bump structures 93. The first non-conductive structure CS1 may include a first non-conductive material layer 50 and a second non-conductive material layer 60 on the first non-conductive material layer 50.

The first non-conductive material layer 50 may include first fillers 51 and a first insulating layer 52. For example, the first insulating layer 52 may include a polymer, and the first fillers 51 may include ceramic particles. The first fillers 51 may be porous fillers. Each of the first fillers 51 may include a plurality of pores.

The second non-conductive material layer 60 may include second fillers 61 and a second insulating layer 62. For example, the second insulating layer 62 may include a polymer, and the second fillers 61 may include ceramic particles. The second fillers 61 may not include pores.

A size of each of the first fillers 51 may be the same as or different from a size of each of the second fillers 61. For example, the size of each of the first fillers 51 may be smaller than the size of each of the second fillers 61, but the present disclosure is not limited thereto. Each size and the number of the first fillers 51 and the second fillers 61 are not limited to those shown in FIG. 11.

The first insulating layer 52 and the second insulating layer 62 may have different viscosities from one another. For example, the viscosity of the first insulating layer 52 may be lower than that of the second insulating layer 62. In this case, the lowest viscosity (or the highest viscosity) of the first insulating layer 52 at a predetermined temperature may be lower than the lowest viscosity (or the highest viscosity) of the second insulating layer 62 at the predetermined temperature.

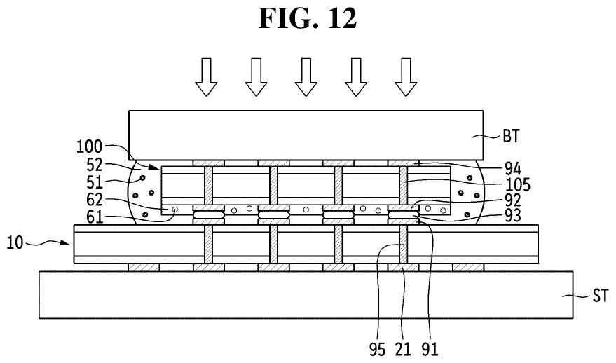

Referring to FIG. 12, a thermal compression bonding process may be performed using a bonding tool BT. The thermal compression bonding process may be performed at a high temperature of about 300° C., but is not limited thereto.

Accordingly, the first non-conductive structure (CS1 of FIG. 11) may be compressed between the base chip 10 and the first semiconductor chip 100, and the bump structures 93 and the upper pads 91 may be in contact with one another. The first non-conductive structure (CS1 of FIG. 11) may surround sides of the bump structures 93 and sides of the upper pads 91.

According to the thermal compression bonding process described above, the first insulating layer 52 having a low viscosity may further extend on the side of the first semiconductor chip 100. Accordingly, the first fillers 51 in the first insulating layer 52 may be also arranged on the side of the first semiconductor chip 100. Although not shown in detail, at least a portion of the second insulating layer 62 and the second fillers 61 may be also arranged on the side of the first semiconductor chip 100 in accordance with the thermal compression bonding process described above.

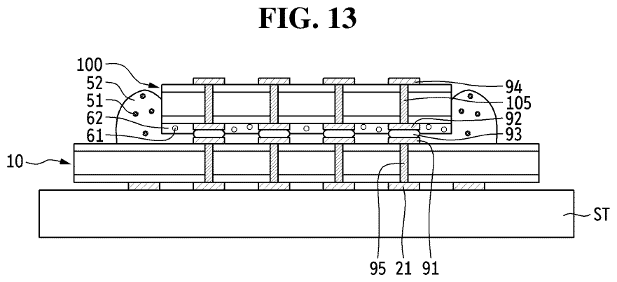

Referring to FIG. 13, the bonding tool BT on the first semiconductor chip 100 may be released. As a result, the first rear pads 94 may be exposed onto the rear surface of the first semiconductor chip 100.

Afterwards, a plurality of semiconductor chips (200 to 700 of FIG. 2) may be stacked on the rear surface of the first semiconductor chip 100. A mold layer (800 of FIG. 2) sealing the plurality of semiconductor chips (100 to 700 of FIG. 2) may be formed on the base chip 10.

Although not shown in detail, the second to seventh non-conductive structures (CS2 to CS7 of FIG. 2) may be also formed between the plurality of semiconductor chips (100 to 700 of FIG. 2). Each of the second to seventh non-conductive structures (CS2 to CS7 of FIG. 2) may include a filler and an insulating layer, which are the same as those of the first non-conductive structure CS1 described above. In this case, each of the second to seventh non-conductive structures (CS2 to CS7 of FIG. 2) may include at least one filler including a plurality of pores.

Through this process, the semiconductor package described with reference to FIGS. 1 to 6 may be fabricated.

In order to stack and fix the plurality of semiconductor chips 100 to 700 on the base chip 100, thermal compression bonding may be performed as described above. In this process, the non-conductive film is more protruded than the sides of the plurality of semiconductor chips 100 to 700 to form a fillet, and such a fillet may cause a defect in appearance and deterioration in reliability of the semiconductor package.

The semiconductor package of some embodiments may include first and second non-conductive material layers 50 and 60 having different viscosities and/or different physical properties between chips. For example, as the second non-conductive material layer 60 having a high viscosity is used, the fillet may be reduced, and as the first non-conductive material layer 50 having a low viscosity is used, a gap-fill property between chips may be improved.

Also, in the above-described bonding process of high-temperature, the non-conductive film between the chips may be thermally decomposed, thereby generating a by-product. For example, the by-product may be a compound containing at least one of carbon (C), oxygen (O), nitrogen (N), or hydrogen (H). Such a by-product may cause a crack or the like between the surface of the chip and the non-conductive film, thereby causing deterioration in reliability of the semiconductor package.

The semiconductor package according to some embodiments may include a porous non-conductive film between chips. For example, the first non-conductive material layer 50 may have a large surface area due to a structure having a plurality of pores, and the by-product may be adsorbed in the pores in a large amount. For example, when the first filler 51 of the first non-conductive material layer 50 contains silica (SiO₂), the by-product may be adsorbed to silica by a hydrogen bond at a molecular level. Accordingly, deterioration in reliability of the semiconductor package, which is caused by the deposition of the by-product on the surface of the chip, may be avoided.

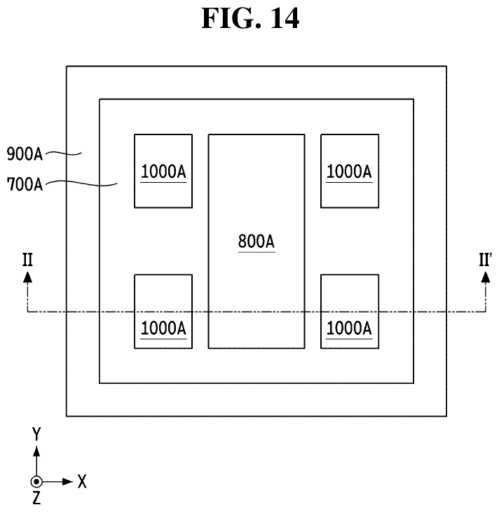

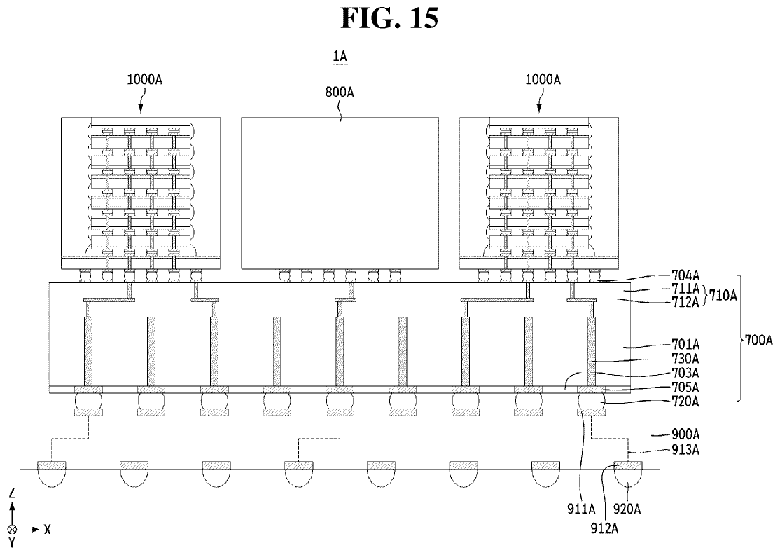

FIG. 14 is a schematic plan view illustrating a semiconductor package according to some embodiments. FIG. 15 is a cross-sectional view taken along line II-II′ of FIG. 14. For convenience of description, redundant portions of those described with reference to FIGS. 1 to 13 will be briefly described or omitted.

Referring to FIGS. 14 and 15, a semiconductor package 1A according to some embodiments may include a package substrate 900A, an interposer substrate 700A, at least one chip structure 1000A, and a processor chip 800A. The chip structure 1000A may have the same or similar characteristics as or to the semiconductor package 1000A described with reference to FIG. 2.

The package substrate 900A may be a support substrate in which the interposer substrate 700A, the processor chip 800A, and the chip structure 1000A are packaged, and may be a substrate for a semiconductor package including a printed circuit board (PCB), a ceramic substrate, a glass substrate, a tape wiring substrate, and the like. A body of the package substrate 900A may include different materials depending on a type of the substrate. For example, when the package substrate 900A is a printed circuit board, the body may have a form of a copper clad laminate or a form in which a wiring layer is additionally stacked on one surface or both surfaces of the copper clad laminate.

The package substrate 900A may include a lower terminal 912A, an upper terminal 911A, and a redistribution circuit 913A. The upper terminal 911A, the lower terminal 912A, and the redistribution circuit 913A may form an electrical path connecting a lower surface with an upper surfaces of the package substrate 900A. The upper terminal 911A, the lower terminal 912A, and the redistribution circuit 913A may include a metal material, for example, at least one of copper (Cu), aluminum (A1), nickel (Ni), silver (Ag), gold (Au), platinum (Pt), tin (Sn), lead (Pb), titanium (Ti), chromium (Cr), palladium (Pd), indium (In) or zinc (Zn), or an alloy containing at least two metals. An external connection terminal 920A connected to the lower terminal 912A may be arranged on a lower surface of the package substrate 900A. The external connection terminal 920A may include tin (Sn), indium (In), bismuth (Bi), antimony (Sb), copper (Cu), silver (Ag), zinc (Zn), lead (Pb), and/or their alloy.

The interposer substrate 700A may include a substrate 701A, a lower protective layer 703A, a lower pad 705A, an interconnection structure 710A, a metal bump 720A, and a through via 730A. The chip structure 1000A and the processor chip 800A may be electrically connected to one another via the interposer substrate 700A.

The substrate 701A may be formed of any one of, for example, silicon, an organic material, plastic, and a glass substrate. When the substrate 701A is a silicon substrate, the interposer substrate 700A may be referred to as a silicon interposer. Unlike the shown example, when the substrate 701A is an organic substrate, the interposer substrate 700A may be referred to as a panel interposer.

The lower protective layer 703A may be arranged on a lower surface of the substrate 701A, and the lower pad 705A may be arranged in the lower protective layer 703A. The lower pad 705A may be connected to the through via 730A. The chip structure 1000A and the processor chip 800A may be electrically connected to the package substrate 900A through metal bumps 720A arranged below the lower pad 705A.

The interconnection structure 710A is arranged on an upper surface of the substrate 701A, and may include an interlayer insulating layer 711A and a single-layered or multi-layered wiring structure 712A. When the interconnection structure 710A is formed of a multi-layered wiring structure, wiring patterns of different layers may be connected to one another through contact vias.

The through via 730A may extend from the upper surface to the lower surface of the substrate 701A to pass through the substrate 701A. Furthermore, the through via 730A may extend into the interconnection structure 710A and thus be electrically connected to wirings of the interconnection structure 710A. When the substrate 701A is silicon, the through via 730A may be referred to as a TSV. According to the embodiment, the interposer substrate 700A may include only the interconnection structure therein, and may not include the through via.

The interposer substrate 700A may be used for converting or transferring an input electrical signal between the package substrate 900A and the chip structure 1000A or the processor chip 800A. Accordingly, the interposer substrate 700A may not include elements such as an active element or a passive element. Also, according to the embodiment, the interconnection structure 710A may be arranged below the through via 730A. For example, a position relation between the interconnection structure 710A and the through via 730A may be relative.

The metal bump 720A may electrically connect the interposer substrate 700A to the package substrate 900A. The chip structure 1000A may be electrically connected to the metal bump 720A through wirings of the interconnection structure 710A and the through vias 730A. According to the embodiment, the lower pads 705A used for power or ground may be integrated and connected to the metal bump 720A, so that the number of the lower pads 705A may be greater than the number of the metal bumps 720A.

The processor chip 800A may include, for example, a central processor (CPU), a graphic processor (GPU), a field programmable gate array (FPGA), a digital signal processor (DSP), an encryption processor, a microprocessor, a microcontroller, an analog-to-digital converter, and an application specific integrated circuit (ASIC) semiconductor.

According to the embodiment, the semiconductor package 1A may further include an inner sealing material (not shown) covering the chip structure 1000A and the processor chip 800A on the interposer substrate 700A. Also, the semiconductor package 1A may further include an outer sealing material (not shown) covering the interposer substrate 700A and the inner sealing material on the package substrate 900A. The outer sealing material and the inner sealing material may be formed together, and thus may not be distinguished from one another. According to the embodiment, the semiconductor package 1A may further include a heat dissipation structure (not shown) covering the chip structure 1000A and the processor chip 800A.

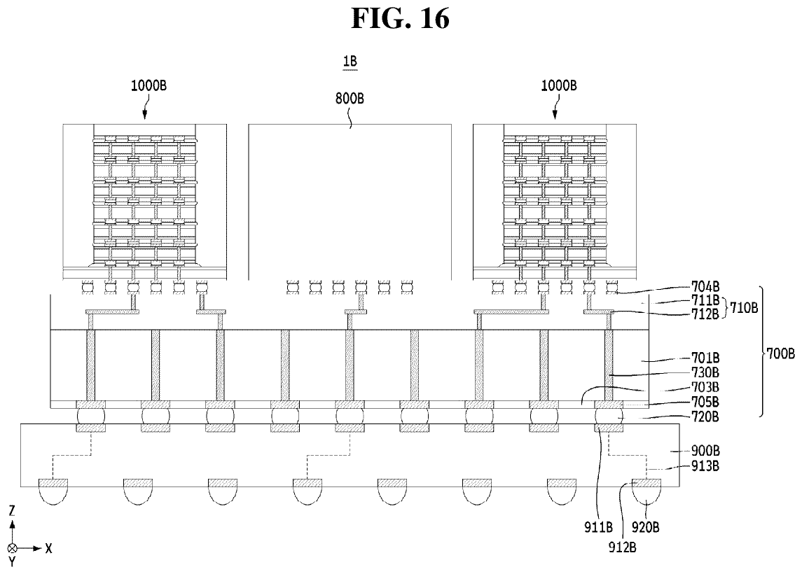

FIG. 16 is a cross-sectional view illustrating a semiconductor package according to some embodiments. For convenience of description, redundant portions of those described above with reference to FIGS. 1 to 15 will be briefly described or omitted. For reference, FIG. 16 is a view corresponding to FIG. 15.

Referring to FIG. 16, a semiconductor package 1B according to some embodiments may include a package substrate 900B, an interposer substrate 700B, at least one chip structure 1000B, and a processor chip 800B. The chip structure 1000B may have the same or similar characteristics as or to the semiconductor package 1000B described with reference to FIG. 10.

The package substrate 900B is a support substrate in which the interposer substrate 700B, the processor chip 800B, and the chip structure 1000B are packaged, and may be a substrate for a semiconductor package including a printed circuit board (PCB), a ceramic substrate, a glass substrate, a tape wiring substrate, and the like. A body of the package substrate 900B may include different materials depending on a type of the substrate. For example, when the package substrate 900B is a printed circuit board, the body may have a form of a copper clad laminate or a form in which a wiring layer is additionally stacked on one surface or both surfaces of the copper clad laminate.

The package substrate 900B may include a lower terminal 912B, an upper terminal 911B, and a redistribution circuit 913B. The upper terminal 911B, the lower terminal 912B, and the redistribution circuit 913B may form an electrical path connecting a lower surface with an upper surface of the package substrate 900B. The upper terminal 911B, the lower terminal 912B, and the redistribution circuit 913B may include a metal material, for example, at least one of copper (Cu), aluminum (A1), nickel (Ni), silver (Ag), gold (Au), platinum (Pt), tin (Sn), lead (Pb), titanium (Ti), chromium (Pd), palladium (In), indium (In), zinc (Zn) or carbon (C), or an alloy containing at least two metals. An external connection terminal 920B connected to the lower terminal 912B may be arranged on the lower surface of the package substrate 900B. The external connection terminal 920B may include tin (Sn), indium (In), bismuth (Bi), antimony (Sb), copper (Cu), silver (Ag), zinc (Zn), lead (Pb), and/or their alloy.

The interposer substrate 700B may include a substrate 701B, a lower protective layer 703B, a lower pad 705B, an interconnection structure 710B, a metal bump 720B, and a through via 730B. The chip structure 1000B and the processor chip 800B may be electrically connected to one another via the interposer substrate 700B.

The substrate 701B may be formed of any one of, for example, silicon, an organic material, plastic, and a glass substrate. When the substrate 701B is a silicon substrate, the interposer substrate 700B may be referred to as a silicon interposer. Unlike the shown example, when the substrate 701B is an organic substrate, the interposer substrate 700B may be referred to as a panel interposer.

The lower protective layer 703B may be arranged on a lower surface of the substrate 701B, and the lower pad 705B may be arranged in the lower protective layer 703B. The lower pad 705B may be connected to the through via 730B. The chip structure 1000B and the processor chip 800B may be electrically connected to the package substrate 900B through the metal bumps 720B arranged below the lower pad 705B.

The interconnection structure 710B is arranged on an upper surface of the substrate 701B, and may include an interlayer insulating layer 711B and a single-layered or multi-layered wiring structure 712B. When the interconnection structure 710B is formed of a multi-layered wiring structure, wiring patterns of different layers may be connected to one another through contact vias.

The through via 730B may extend from the upper surface to the lower surface of the substrate 701B to pass through the substrate 701B. Also, the through via 730B may extend into the interconnection structure 710B and thus be electrically connected to the wirings of the interconnection structure 710B. When the substrate 701B is silicon, the through via 730B may be referred to as a TSV. According to the embodiment, the interposer substrate 700B may include only the interconnection structure therein, and may not include the through via.

The interposer substrate 700B may be used for converting or transferring an input electrical signal between the package substrate 900B and the chip structure 1000B or the processor chip 800B. Accordingly, the interposer substrate 700B may not include elements such as an active element or a passive element. Also, according to the embodiment, the interconnection structure 710B may be arranged below the through via 730B. For example, the position relation between the interconnection structure 710B and the through via 730B may be relative.

The metal bump 720B may electrically connect the interposer substrate 700B to the package substrate 900B. The chip structure 1000B may be electrically connected to the metal bump 720B through wirings of the interconnection structure 710B and the through vias 730B. According to the embodiment, the lower pads 705B used for power or ground may be integrated and connected to the metal bump 720B, so that the number of the lower pads 705B may be greater than the number of the metal bumps 720B.

The processor chip 800B may include, for example, a central processor (CPU), a graphic processor (GPU), a field programmable gate array (FPGA), a digital signal processor (DSP), an encryption processor, a microprocessor, a microcontroller, an analog-to-digital converter, and an application specific integrated circuit (ASIC) semiconductor.

Although the embodiments of the present disclosure have been described with reference to the accompanying drawings, it will be apparent to those skilled in the art that the present disclosure may be fabricated in various forms without being limited to the above-described embodiments and may be embodied in other specific forms without departing from the technical spirits and essential characteristics. Thus, the above embodiments are to be considered in all respects as illustrative and not restrictive.

What is claimed is:

1. A semiconductor package comprising:
a first semiconductor chip;
a second semiconductor chip arranged on the first semiconductor chip; and
a non-conductive structure arranged between the first semiconductor chip and the second semiconductor chip,
wherein the non-conductive structure includes a filler including a plurality of pores.

2. The semiconductor package of claim 1, wherein the non-conductive structure includes a first non-conductive material layer and a second non-conductive material layer on the first non-conductive material layer,
the first non-conductive material layer includes a first insulating layer and a first filler,
the second non-conductive material layer includes a second insulating layer and a second filler, and
the first filler is a porous filler.

3. The semiconductor package of claim 2, wherein the second filler is a porous filler.

4. The semiconductor package of claim 2, wherein the first non-conductive material layer further includes a third filler having no pores.

5. The semiconductor package of claim 2, wherein the first non-conductive material layer has a viscosity lower than that of the second non-conductive material layer.

6. The semiconductor package of claim 2, wherein the first semiconductor chip extend in first and second horizontal directions crossing one another, and
a width of the first non-conductive material layer is greater than that of the second non-conductive material layer based on the first horizontal direction.

7. The semiconductor package of claim 1, wherein at least one of the plurality of pores includes a first region and a second region on the first region,
the first region includes a carbon (C) compound, and
the second region includes a polymer.

8. The semiconductor package of claim 1, wherein the non-conductive structure includes a first filler, a second filler, and an insulating layer in which the first and second fillers are dispersed,
the first filler is a porous filler, and
the second filler has no pores.

9. The semiconductor package of claim 1, further comprising:
a mold layer covering sides of each of the first and second semiconductor chips and sides of the non-conductive structure;
a first through via passing through the first semiconductor chip; and
a second through via passing through the second semiconductor chip.

10. A semiconductor package comprising:
a base chip;
a semiconductor chip structure, in which a plurality of semiconductor chips are stacked, on the base chip; and
a non-conductive structure, which includes a first non-conductive material layer and a second non-conductive material layer on the first non-conductive material layer, between the base chip and the semiconductor chip structure,
wherein:
the first non-conductive material layer includes a first insulating layer and a first filler in the first insulating layer,
the second non-conductive material layer includes a second insulating layer and a second filler in the second insulating layer,
the first filler includes a plurality of pores, and
the second filler does not include pores.

11. The semiconductor package of claim 10, wherein:
the first filler includes a first region and a second region on the first region,
the first region includes at least one of carbon (C), oxygen (O), nitrogen (N), or hydrogen (H), and
the second region includes a material which is the same as a material included in the first insulating layer.

12. The semiconductor package of claim 10, wherein the first non-conductive material layer has a viscosity different from that of the second non-conductive material layer.

13. The semiconductor package of claim 10, wherein the first filler has a size different from that of the second filler.

14. The semiconductor package of claim 10, wherein the first filler has a diameter of 1 nm to 50 nm, and the second filler has a diameter of 100 nm to 10 μm.

15. The semiconductor package of claim 10, wherein the first and second insulating layers include a polymer.

16. The semiconductor package of claim 10, wherein the first and second fillers include at least one of SiO₂, ZrO₃, HfO₂ or TiO₂.

17. A semiconductor package comprising:
a base chip;
a semiconductor chip structure, in which a plurality of first and second semiconductor chips are sequentially stacked, on the base chip; and
a first insulating structure, which includes a first non-conductive material layer and a second non-conductive material layer on the first non-conductive material layer, between the base chip and the first semiconductor chip;
a second insulating structure, which includes a third non-conductive material layer and a fourth non-conductive material layer on the third non-conductive material layer, between the first semiconductor chip and the second semiconductor chip;
a mold layer, which covers sides of each of the first and second semiconductor chips, on the base chip; and
through vias passing through each of the first and second semiconductor chips,
wherein:
the first non-conductive material layer includes a porous first filler,
the second non-conductive material layer includes a second filler different from the first filler,
the third non-conductive material layer includes a porous third filler, and
the fourth non-conductive material layer includes a fourth filler different from the third filler.

18. The semiconductor package of claim 17, wherein:
the first filler includes a first region containing a first carbon compound and a second region containing a first polymer, and
the third filler includes a third region containing a second carbon compound and a fourth region containing a second polymer.

19. The semiconductor package of claim 17, wherein the first non-conductive material layer is more protruded from a side of the semiconductor chip structure than the second non-conductive material layer.

20. The semiconductor package of claim 17, wherein each of the second filler and the fourth filler does not include pores.
